(19) United States
(12) Patent Application Publication
(10) Pub. No.: US 2015/0114568 A1
(43) Pub. Date: Apr. 30, 2015

(54) PLASMA PROCESSING APPARATUS

(71) Applicant: Hitachi High-Technologies Corporation, Tokyo (JP)

(72) Inventors: Yutaka Kudo, Tokyo (JP); Hiroaki Takikawa, Tokyo (JP); Takahiro Sakuragi, Tokyo (JP)

(21) Appl. No.: 14/182,259

(22) Filed: Feb. 17, 2014

(30) Foreign Application Priority Data
Oct. 30, 2013 (JP) 2013-224883

(51) Int. Cl. H01L 21/02

(52) U.S. Cl. CPC H01L 21/02002
USPC 156/345.54

(57) ABSTRACT

A plasma processing apparatus including a wafer stage disposed in a processing chamber arranged in a vacuum chamber to hold a wafer as a processing object on a surface of the wafer stage, to conduct processing for the wafer by use of plasma, wherein the wafer includes grooves, each of the grooves extending from a central portion of a surface on which the wafer is held to an outer circumferential edge of the surface, the grooves including openings at the outer circumferential edge, and the processing is conducted in a state in which the wafer is held at predetermined height over an upper surface of the wafer stage.

### BACKGROUND OF THE INVENTION

The present invention relates to a plasma processing apparatus in which a sample such as a semiconductor wafer disposed in a processing chamber decompressed in a vacuum chamber is processed by use of plasma generated in the processing chamber, and in particular, to a plasma processing apparatus in which a sample is mounted on a stage disposed in the processing chamber and a film as a processing object on a surface of the sample is ashed.

In an ashing apparatus to be employed to produce semiconductor devices, various problems arise due to the positional shift of the wafer on the stage in the processing chamber.

Occurrence of the positional shift of the wafer on the stage causes not only interruption of the processing to manufacture devices but also an operation to open the processing chamber to an atmospheric environment to remove the wafer therefrom. When the positional shift is large, the wafer may be broken during transfer thereof. In such situation, it is required to conduct wet cleaning and the processing for the devices is interrupted. Hence, it is essential to prevent the positional shift of the wafer on the stage. On the other hand, the positional shift of the wafer also causes to generate contaminating materials due to friction between the rear surface of the wafer and a member of the wafer stage.

Heretofore, techniques to remove the problem have been known. For example, JP-A-2002-057210 describes a wafer stage to prevent the positional shift of the wafer on the stage and to reduce contaminating materials. Also, JP-A-2012-142447 describes a configuration including a plurality of annular air exhaust groove and linear groove extending to pass a center of the spacer member and communicatively connect both end edges thereof to each other disposed on an upper surface of a spacer member mounted over an upper surface of the wafer stage.

Further, JP-A-2012-054399 describes a technique wherein occurrence of contaminating materials is prevented by reducing the contact area between the wafer and wafer stage when a wafer is adsorbed by electrostatic adsorption. Further, JP-A-2007-235116 describes a technique in which warp of the wafer is suppressed in a processing apparatus including a high-temperature wafer holding stage.

### SUMMARY OF THE INVENTION

However, since consideration has not fully given to the point below, a problem has arisen as follows.

The cause of the positional shift of the wafer on the stage is found by the present inventors as below. That is, between the rear surface of the wafer and the upper surface of the wafer stage, pressure of gas becomes higher, and upward force appears due to the pressure of the gas and lifts the wafer. The wafer hovers and the positional shift of the wafer takes place. The increase in pressure on the rear surface of the wafer is caused as below. When the wafer is mounted on the wafer stage heated up to a high temperature in the ashing apparatus and the like and then closely approaches the upper surface thereof, the wafer warps upward in the convex shape.

It is likely that when stress is applied to a film formed on the wafer, stress of the film results in the force to cause the warp in the wafer. When the wafer warps upward in the convex shape, gas is collected in a space between the rear surface of the wafer and the upper surface of the wafer stage. Hence, pressure on the rear surface of the wafer increases and causes the hovering of the wafer.

It can be considered that in a wafer in which a film is formed also on a rear surface of the wafer, there occurs degassing from the rear surface of the wafer due to thermal energy. This causes the hovering of the wafer. In the conventional techniques described above, consideration has not been given to reduction of the increase in gas pressure on the rear surface side due to the convex warp of the wafer as a cause of the wafer positional shift, neither to the suppression of the hovering of the wafer as a cause of the wafer positional shift. Hence, yield and efficiency in the processing are deteriorated due to occurrence of contaminating materials caused by the positional shift of the wafer or due to an event in which when the wafer mounted on an arm of a transfer robot is lifted from the stage and is transferred, the wafer falls from the arm or collides against a member in the inside of the processing apparatus and is damaged.

It is therefore an object of the present invention to provide a plasma processing apparatus to conduct plasma processing at a high temperature in which the positional shift of the wafer is suppressed on the wafer stage, to thereby increase efficiency of the plasma processing.

In order to achieve the object, there is provided a plasma processing apparatus comprising a wafer stage disposed in a processing chamber arranged in a vacuum chamber to hold a wafer as a processing object on a surface of the wafer stage, to conduct processing for the wafer by use of plasma generated in the processing chamber, wherein

the wafer stage comprises grooves, each of the grooves extending from a central portion of a surface on which the wafer is held to an outer circumferential edge of the surface, the grooves including openings at the outer circumferential edge, and the processing is conducted in a state in which the wafer is held at predetermined height over an upper surface of the wafer stage.

### BRIEF DESCRIPTION OF THE DRAWINGS

FIG. 1 is a longitudinal cross-sectional diagram to explain an outline of the configuration of a plasma processing apparatus in an embodiment.

FIGS. 2A and 2B are longitudinal cross-sectional view and an upper view to show an outline of the configuration of the wafer stage according to the present embodiment shown in FIG. 1 and FIG. 2C is an upper view to show an outline of the configuration of the wafer stage according to the prior art.

FIG. 3A and FIG. 3B are figures for explaining factors of the wafer position shift.

FIG. 4A is a graph comparing ashing rates of a thermal oxidation film on a wafer stage according to the prior art and a wafer stage of the present invention.

FIG. 4B is a graph comparing ashing rates of a carbon film on a wafer stage according to the prior art and a wafer stage of the present invention.

### DESCRIPTION OF THE EMBODIMENTS

Description will now be given of an embodiment of the present invention by referring to the drawings.

### EMBODIMENT

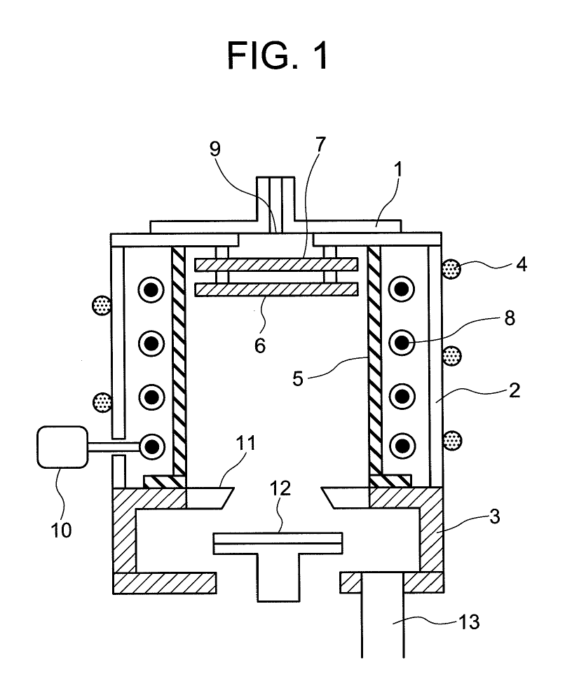

FIG. 1 shows, in a longitudinal cross-sectional diagram, an outline of the configuration of a plasma processing apparatus in an embodiment of the present invention. For the embodiment, description will be given of an ashing apparatus using plasma as a plasma processing apparatus. The plasma ashing apparatus is a downflow ashing apparatus wherein in a processing chamber in an inside of a vacuum chamber which is decompressed by use of a helical antenna to a predetermined degree of vacuum and which is kept in the decompressed state, plasma of induction coupling type is generated, and a wafer is mounted on an upper surface of a wafer stage disposed at an lower position in the processing chamber and then ashing is conducted for a target film such as a mask, e.g., photo-resist on a surface of the wafer.

The vacuum chamber of the ashing apparatus of the embodiment includes a circular top plate 1 mounted on an upper section of the vacuum chamber with a seal member such as an O ring to airtightly seal the vacuum chamber, the seal member being interpolated between the vacuum chamber and a lower surface of an outer circumferential edge of the top plate 1. The vacuum chamber further includes a cylindrical quartz chamber 5 including dielectric such as quartz disposed below and in contact with the outer circumferential edge and an aluminum chamber 3 disposed below the quartz chamber 5 to be connected to a lower edge of the quartz chamber 5, the aluminum chamber 3 having the shape of substantially a parallelepiped or having the shape of a box having a polygonal shape in the top view.

In the top plate 1, one or more gas supply hole or holes 9 is or are disposed in a central section as a through hole or holes to supply process gas to the processing chamber which is to be decompressed to vacuum. Just beneath the gas supply hole or holes 9, two quartz baffle plates 6 and 7 are disposed to configure ceiling surfaces of the processing chamber.

Of the two quartz baffle plates 6 and 7, the upper one, i.e., the first baffle plate 7 is arranged below the gas supply hole or holes 9 of the top plate 1 at a position about several millimeters apart from the gas supply hole or holes 9, to prevent abnormal discharge which takes place in the vicinity the gas supply hole or holes 9. The lower one baffle plate, i.e., the second baffle plate 6 is arranged below the gas supply hole or holes 9 at a position about several centimeters apart from the baffle plate 7, to efficiently disperse gas, which flows from the first baffle plate 7 into the quartz chamber 5, to the outer circumference of the second baffle plate 6.

The quartz chamber 5 includes quartz having a cylindrical shape. On the outer circumference of the outer sidewall of the quartz chamber 5, an induction coil 8 is helically wound a plurality of times at an equal interval, with a gap between the quartz chamber 5 and the induction coil 8. When the induction coil 8 is supplied with high-frequency power at 27.12 MHz from a power source 10, the induction coil 8 helically generates induced magnetic field or induced field along the position of the induction coil 8, in a space inside the cylindrical processing chamber of the quartz chamber 5, the space being apart by a predetermined distance from the surface of the inner sidewall of the processing chamber. The induced field excites molecules or atoms of the process gas supplied from the gas supply hole or holes 9 to the processing chamber, to thereby generate plasma.

The height of the quartz chamber 5 of the embodiment is designed such that on a surface of a wafer 20 as a sample mounted on a circular upper surface of a circular wafer stage 12 disposed at a lower position in the processing chamber, plasma which is generated by the induced field in the vicinity of the induction coil 8 at an upper position and which diffuses and moves downward is uniformly distributed. At an outer circumference of the induction coil 8, to prevent leakage of the high-frequency power to the outside, a shield 2 equipped with a water-cooling mechanism 4 is arranged such that the cylindrical outer wall is cover with the shield 2.

The plasma or the process gas proceeds along the inner wall of the quartz chamber 5. In the chamber 3 beneath the quartz chamber 5, the plasma or the process gas diffuses toward the wafer 20 as a sample mounted on the wafer stage 12 disposed with its central axis set to align with that of the quartz chamber 5, to be supplied onto the surface of the wafer. The plasma or the process gas moves, while diffusing from the central side of the circular wafer 20 or from the central side of the wafer stage 12 having the shape of a cylinder or a disk, to the outer circumferential side thereof. To improve uniformity in strength or density of the plasma or the process gas on the wafer 20, an aluminum rectifier ring 11 is disposed between the aluminum chamber 3 and the quartz chamber 5.

An inner circumferential edge section constituting a circular space disposed on an inner side of the rectifier ring 11 has, in a longitudinal cross section, a tapered shape extending and widening toward the wafer 20 therebeneath. This shape is designed for the following purpose. As above, the induced field has the strongest zone in the inside of the inner wall of the quartz chamber 5 along the induction coil 8, and the generated plasma has also the strongest zone in the same area. Hence, when viewed on a line or plane along the inner sidewall of the quartz chamber 5, the plasma is not uniformly generated. However, by disposing the rectifier ring 11, it is possible to suppress an event in which the plasma moving from above along the inner sidewall directly arrives at the wafer 20 at the lower position and the plasma distribution takes a high value in the outer circumference. This resultantly reduces unevenness in the processing on the wafer 20.

The process gas supplied from the gas supply hole or holes 9 flows along the inner wall of the quartz chamber 5 through a space near the induction coil 8, to thereby efficiently generate the plasma. The film as the processing object disposed on the upper surface of the wafer 20 is ashed by the plasma. Byproducts produced through the ashing and the process gas not reacted are exhausted from an exhaust hole 13 by a vacuum pump such as a dry pump, not shown. The pump is disposed below the chamber 3 to decompress the processing chamber coupled via the exhaust hole 13 to the inside of the chamber 3.

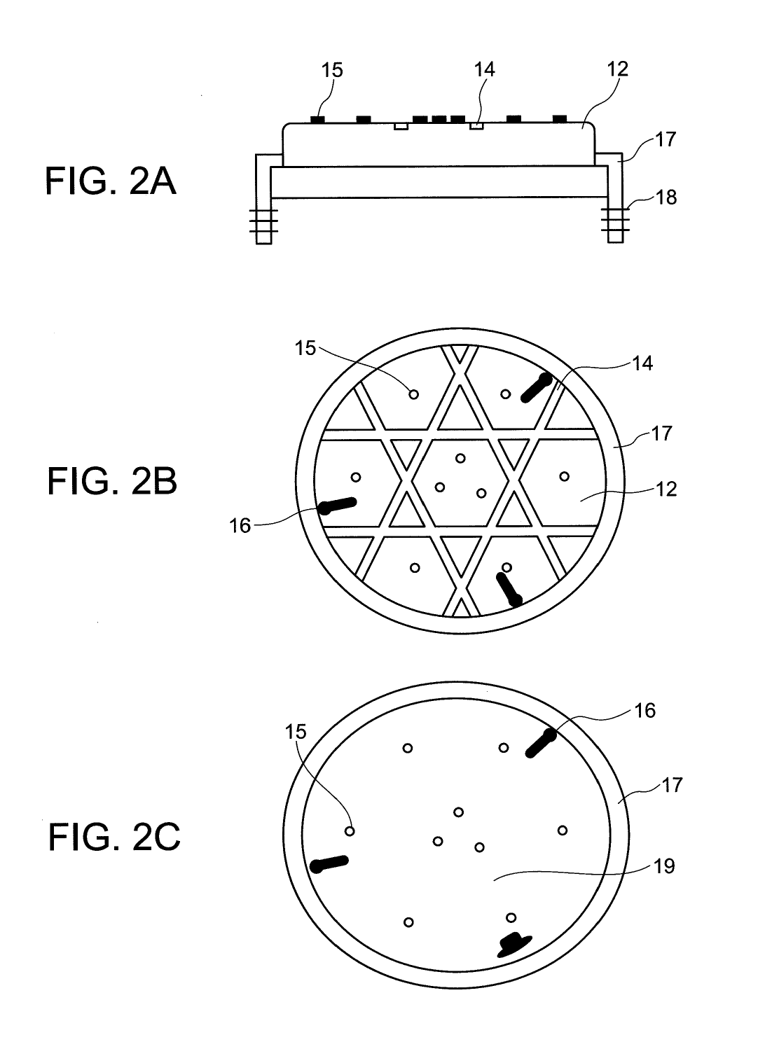

Referring now FIGS. 2A, 2B, and 2C, description will be given of the configuration of the wafer stage according to the prior art and the present embodiment. FIGS. 2A and 2B are longitudinal cross-sectional view and an upper view to show an outline of the configuration of the wafer stage according to the present embodiment shown in FIG. 1 and FIG. 2C is an upper view to show an outline of the configuration of the wafer stage according to the prior art.

In the drawings, each of the wafer stages 12 and 19 includes a cylindrical or circular aluminum member, and on an upper surface thereof, a 0.15 mm high aluminum proxy pin 15 is disposed at nine positions.

The wafer 20 is mounted to be held on the nine proxy pins 15 with a predetermined gap between the wafer 20 and the upper surface of the wafer stage 12 or 19. The wafer 20 is heated up, by thermal conduction via the process gas through the gap between the wafer 20 and the wafer stage 12 or 19, to a high temperature (300° C. in this embodiment) suitable for the processing. Further, since the wafer 20 is placed not to directly make contact with the upper surface of the wafer stage 12 or 19, contamination on the rear surface of the wafer 20 due to such contact is reduced.

When the height of the tip end of the proxy pin 15 relative to the upper surface of the wafer stage 12 or 19 is 0.15 mm or more, the efficiency of thermal conduction between the wafer 20 and the wafer stage 12 or 19 abruptly lowers and heat is not easily transferred. Hence, it is required to elongate the period of time to heat up the wafer 20 to the temperature suitable for the processing. However, when the period of time to heat up the wafer 20 to the appropriate temperature is elongated, the overall processing time from when the wafer 20 is transferred to the inside of the plasma processing apparatus (plasma ashing apparatus) to when the ashing is completely finished is also elongated. Hence, the throughput or the number of wafers 20 processed per unitary time is lowered.

When the height of the tip end of the proxy pin 15 is increased, the influence from exhaust on the outer circumference of the wafer 20 is more easily exerted. The outer circumference of the wafer 20 is lower in temperature than the central region of the wafer 20. This increases unevenness in the distribution of the ashing rate in the surface. In consideration of this phenomenon, the tip end of the proxy pin 15 of the present embodiment is set to 0.15 mm not, to thereby suppress the adverse affect on the ashing performance.

At a lower portion of the outer circumferential sidewall of wafer stage 12 or 19, a cylindrical exhaust baffle 17 is arranged such that the outer circumferential sidewall is enclosed with the exhaust baffle 17. In the exhaust baffle 17, punching holes 18 are arranged as through holes between the inside and the outside the exhaust baffle 17. Byproducts and the process gas not reacted, which are resultant from the ashing conducted on the surface of the wafer 20, flow from the outer circumference side of the lower portion of the wafer 20 via the punching holes 18 into the inside of the exhaust baffle 17 and are then exhausted therefrom. As a result, the unevenness in the circumferential direction of the wafer stage 12 or 19 is suppresses.

Next, description will be given of a configuration of and a forming process for grooves disposed on a front surface of the wafer stage 12 of the present embodiment. To suppress the increase in gas pressure in the space between the rear surface of the wafer 20 and the upper surface of the wafer stage 12 caused by the increase in temperature of the wafer 20 and to thereby reduce the positional shift of the wafer 20, a plurality of grooves 14 having a predetermined shape are disposed on the surface of the wafer stage 12 of the present embodiment.

According to discussion of the present inventors about specifications of width and depth of the shape of the grooves 14, when the grooves 14 are too wide, the temperature distribution on the surface of the wafer stage 12 is adversely affected and the shape of the grooves 14 is transcribed onto the distribution of the ashing rate in the plane and the evenness of the distribution is deteriorated. Further, when the grooves 14 are too narrow, as when the grooves 14 are too wide, the distribution of the ashing rate in the surface deteriorated.

In the wafer stage 12 of the present embodiment, the grooves 14 are disposed to radially extend from the central side to the outer circumference side of the wafer stage 12. However, when the grooves 14 are disposed in the central zone of the wafer stage 12 in a concentrated fashion and the ratio of the area of the grooves 14 per unitary area in the central zone is larger than a particular value when compared with that in the outer circumferential side, quantity of heat transferred from the wafer stage 12 to the wafer 20 is relatively smaller in the central zone than in the outer circumferential side. Hence, the temperature distribution in the surface direction of the wafer 20 is lower in the central section and there exists a fear of deterioration in the evenness of the ashing rate.

As a result of discussion of the present inventors in consideration of the problem described above, it is found that when the groove 14 of the present embodiment is in a contour having a width of 4 mm and a depth of 0.5 mm, the adverse affect on the distribution of the ashing rate in the surface direction of the wafer 20 is suppressed. It is also found that when the grooves 14 are arranged such that the areas sectioned by disposing the grooves 14 on the wafer stage 12 are almost equal to each other in the circumferential direction, the unevenness is reduced in the temperature distribution on the surface of the wafer stage 12.

In the present embodiment, according to the information obtained as above, the grooves 14 are arranged as follows. Three pairs of grooves 14 in which each pair includes two grooves 14 arranged in parallel to each other as shown in FIG. 2B are disposed such that in the circumferential direction with respect to the vicinity of the center of the wafer stage 12, the pairs of grooves 14 have respectively one and the same relative angle, that is, in the equal angular direction. In order that the gas on the rear surface side of the wafer 20 is efficiently introduced to a space on the outer circumference side of the wafer 20 and is exhausted or in order that gas is efficiently fed (by lowering resistance) to or from the space in the processing chamber on the outer circumference side of the wafer 20, the end portion of the groove 14 on the outer circumference of the wafer stage 12 is configured such that in a state in which the wafer 20 is mounted, an opening is formed to communicatively connect the end section of the groove 14 to the inside of the processing chamber.

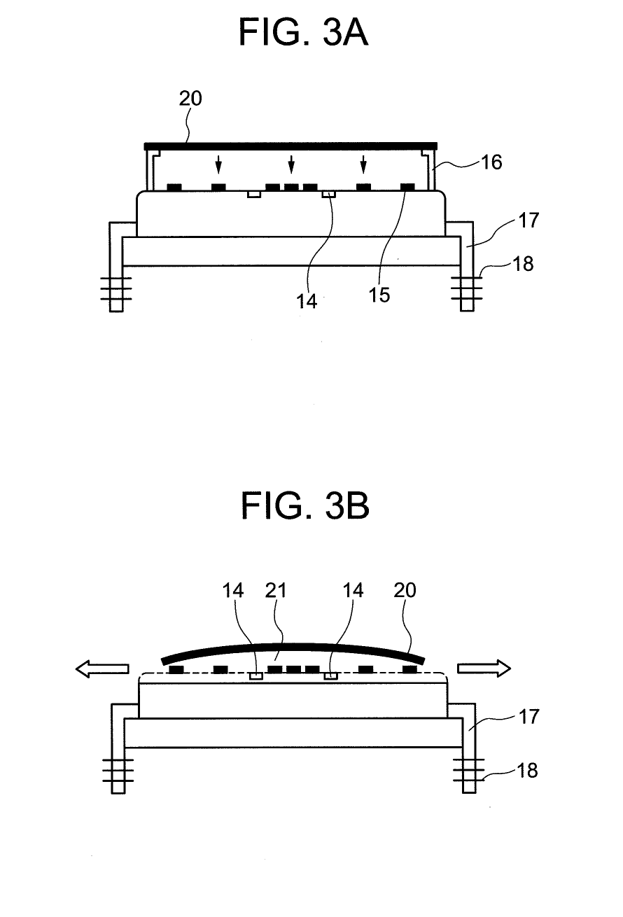

FIGS. 3A and 3B are diagrams to explain a cause of occurrence of the positional shift of the wafer. FIG. 3A shows a state in which the wafer 20 is mounted and is held on lifter pins 16. FIG. 3B shows a state in which the lifter pins 16 are lowered and are stored in the inside of the wafer stage 12 and the wafer 20 is held with its rear surface brought into contact with the tip ends of the lifter pins 16.

The cause of occurrence of the positional shift of the wafer is considered as below. In a state in which the wafer 20 held on the tip ends of the lifter pins 16, when the lifter pins 16 are lowered, the wafer 20 is held on the proxy pins 5 of the wafer stage 12 with a gap between the wafer 20 and the mount surface. In this state, when the wafer 20 is rapidly heated up to about 300° C., stress takes place in the upper and lower portions of the film beforehand formed on the wafer 20 and the wafer warps in the convex direction. Hence, the outer circumferential portion on the rear surface of the wafer 20 makes contact with or is placed in the vicinity of the surface of the wafer stage 12. Gas collected in a space between the convex wafer 20 and the wafer stage 12 expands due to heat. This increases the pressure in a space 21 on the rear surface side of the wafer 20. As a result, the wafer 20 hovers from the tip ends of the proxy pins 15, causing the positional shift of the wafer 20.

On the other hand, it is also considerable that when a carbon film on which thermal reaction easily takes place is formed on the rear surface of the wafer 20, degassing occurs from the film on the rear surface of the wafer 20 due to abrupt thermal reaction. Due to the resultant gas, the pressure becomes higher in the space 21 on the rear surface side of the wafer 20. Hence, the wafer 20 hovers and the positional shift of the wafer 20 occurs. According to discussion of the present inventors, it is found that timing of occurrence of the positional shift of the wafer 20 is as below. The positional shift takes place during the heat-up step before the discharge of the ashing condition as well as during the discharge.

The present inventors has verified the cause of the positional shift of the wafer 20 by using the wafer stage 12 of the present embodiment and the wafer stage 19 of the prior art. For the test of wafers, a wafer sample in which a carbon film on which thermal reaction remarkably takes place and in which film stress easily occurs is formed on both of the front surface and the rear surface of a wafer and a wafer sample in which a carbon film is formed only on the front surface are prepared. The test of the wafer positional shift is carried out by ashing the wafer samples.

Table 1 lists processing conditions for the test. Under the processing conditions, the degassed gas and byproducts are considered to be easily generated in quantity. When the wafer stage 19 of the prior art is used, the positional shift of the wafer occurs for both of the sample in which a carbon film is formed on the front surface and the rear surface of the wafer and the sample in which a carbon film is formed only on the front surface of the wafer. However, when the wafer stage 12 with the grooves of the present embodiment is used, the positional shift of the wafer occurs for none of the samples.

For the sample in which a carbon film is formed only on the front surface, the positional shift of the wafer occurs in the wafer stage 19 of the prior art. Specifically, for the sample in which no degassing occurs from the rear surface of the wafer, the positional shift of the wafer occurs in the wafer stage 19 of the prior art. It is hence found that the positional shift of the wafer occurs as below. When the wafer is abruptly heated up and warps in the convex direction and the edge portion of the wafer makes contact with or is in the vicinity of the surface of the wafer stage 12, gas collected on the rear surface side of the wafer 20 expands due to heat, and the wafer hovers to cause the positional shift of the wafer. It is found that by disposing grooves on the surface of the wafer stage 12 as described above, the gas between the rear surface of the wafer and the wafer stage 12 is efficiently exhausted along the grooves to the outer circumference side of the wafer. This suppresses the increase in the pressure, to thereby remove the problem of the positional shift of the wafer.

TABLE 1
CONVENTIONAL ASHING CONDITIONS

| STEP | H2 | N2 | PRESS | RF POWER | TEMP. | PIN | TIME | |
|---|---|---|---|---|---|---|---|---|
| No. | (L/min) | (L/min) | (Pa) | (w) | (° C.) | (mm) | (s) | PROCESSING |
| 1 | 5 | 5 | 200 | 0 | 300 | 0 | 20 | HEAT-UP |
| 2 | 5 | 5 | 200 | 2000 | 300 | 0 | 60 | ASHING |

Next, description will be given of an advantage of throughput due to use of the wafer stage 12 according to the present invention. The ashing conditions employed for the wafer stage 19 of the prior art includes a step to heat up the wafer and a step to conduct ashing as listed in Table 1.

TABLE 2
ASHING CONDITIONS FOR WAFER POSITIONAL SHIFT SUPPRESSION

| STEP | H2 | N2 | PRESS | RF POWER | TEMP. | PIN | TIME | |
|---|---|---|---|---|---|---|---|---|
| No. | (L/min) | (L/min) | (Pa) | (w) | (° C.) | (mm) | (s) | PROCESSING |
| 1 | 5 | 5 | 200 | 0 | 300 | 1 | 50 | WAFER STRESS |
| | | | | | | | | MITIGATION |
| 2 | 5 | 5 | 200 | 0 | 300 | 0 | 10 | HEAT-UP |
| 3 | 5 | 5 | 200 | 2000 | 300 | 0 | 60 | ASH1NG |

However, the positional shift of the wafer 20 occurs when the processing is conducted by use of the carbon-film wafer. Hence, before the heat-up step conventionally carried out as listed in Table 2, there is added a step in which the wafer 20 is held by use of the lifter pins 16 for 50 seconds at a position one millimeter above the surface of the wafer stage 12. In this process, the warp of the wafer 20 is removed. Thereafter, the conventional heat-up step is carried out.

On the other hand, in the wafer stage 19 of the prior art, the step to mitigate the warp of the wafer 20 is required in any situation. This hence leads to a problem that the ashing time is elongated. For this problem, the wafer positional shift is verified under the processing conditions of Table 1 by use of the carbon-film wafer in the wafer stage 12 of the present invention. This results in no positional shift of the wafer 20.

That is, even step 1 of Table 2 is not employed, no positional shift takes place for the wafer 20. Hence, it is judged that when compared with the processing conditions of Table 2, the total ashing time can be reduced for about 40 seconds and the throughput is increased. Also, by using the wafer stage 12 of the present embodiment, no positional shift occurs for the wafer 20 on the wafer stage 12. Hence, the event of occurrence of dust due to friction between the rear surface of the wafer 20 and the wafer stage 12 can be suppressed.

TABLE 3
VERIFICATION RESULTS FOR WAFER POSITIONAL SHIFT

| | | | WAFER STAGE WITH | |
|---|---|---|---|---|
| | CONVENTIONAL WAFER | | GROOVES OF PRESENT | |
| | MOUNT STAGE | | INVENTION | |
| WAFER | OXYGEN | FLUORINE | OXYGEN | FLUORINE |
| TYPE | CONDITION | CONDITION | CONDITION | CONDITION |
| THERMAL | — | POSITIONAL | — | POSITIONAL |
| OXIDATION | | SHIFT IS | | SHIFT IS NOT |
| FILM | | DETECTED | | DETECTED |
| SILICON | — | POSITIONAL | — | POSITIONAL |
| NITRIDE | | SHIFT IS | | SHIFT IS NOT |
| | | DETECTED | | DETECTED |
| CARBON | POSITIONAL | — | POSITIONAL | — |
| FILM | SHIFT IS | | SHIFT FS | |
| | DETECTED | | NOT | |
| | | | DETECTED | |

Table 3 lists results of the verification of the wafer positional shift obtained by changing the ashing condition for wafers 20 including other than the film structure described above. Even for the film structure types and ashing conditions associated with occurrence of the wafer positional shift in the wafer stage 19 of the prior art, no wafer positional shift takes place in the wafer stage 12 including the grooves 14 according to the present embodiment.

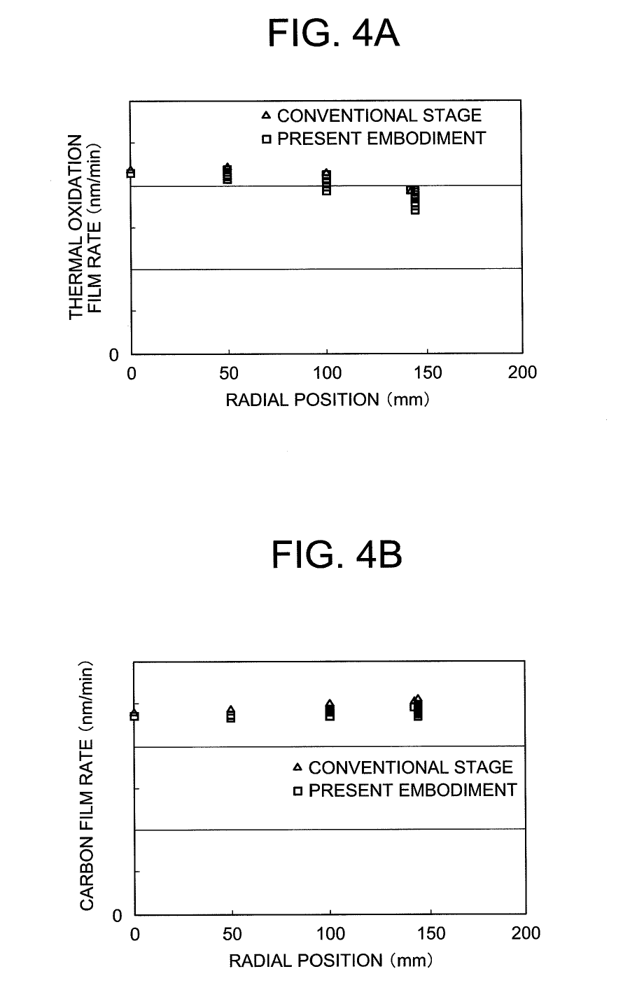

FIGS. 4A and 4B are graphs to compare the ashing rate distribution between the wafer stage 12 of the present embodiment and the wafer stage 19 of the prior art. In the wafer stage 12 including the grooves 14, when the ashing performance remarkably changes as compared with the wafer stage 19 of the prior art, quite a long period of time is required to adjust the ashing condition so as to obtain a desired result. Hence, it is desirable to avoid such remarkable performance change relative to the ashing performance obtained when the wafer stage 19 without the grooves 14 is employed.

TABLE 4
OXYGEN CONDITION USED FOR VERIFICATION
OF WAFER POSITONAL SHIFT

| STEP | O2 | PRESS | RF POWER | TEMP. | PIN | TIME | |
|---|---|---|---|---|---|---|---|
| No. | (L/min) | (Pa) | (w) | (° C.) | (mm) | (s) | PROCESSING |
| 1 | 10 | 500 | 0 | 300 | 0 | 20 | HEAT-UP |
| 2 | 10 | 500 | 4500 | 300 | 0 | 60 | ASHING |

TABLE 5
FLUORINE CONDITIONS USED FOR VERIFICATION
OF WAFER POSITIONAL SHIFT

| STEP | N2 | CF4 | PRESS | RF POWER | TEMP. | PIN | TIME | |
|---|---|---|---|---|---|---|---|---|
| No. | (L/min) | (L/min) | (Pa) | (w) | (° C.) | (mm) | (s) | PROCESSING |
| 2 | 5 | 1 | 200 | 0 | 300 | 0 | 10 | HEAT-UP |
| 3 | 5 | 1 | 200 | 2000 | 300 | 0 | 60 | ASHING |

Under this circumstance, the ashing rate in the surface direction of the wafer 20 is evaluated under the processing conditions listed in Tables 4 and 5 by use of wafers 20 on which a resist film and a thermally oxidized film are respectively formed. As a result, the values and the surface-directional distribution of the ashing rate obtained by use of the wafer stage 12 of the present embodiment have been confirmed equivalent to those obtained by use of the wafer stage 19 of the prior art.

Other objects, features and advantages of the invention will become apparent from the following description of the embodiments of the invention taken in conjunction with accompanying drawings.

1. A plasma processing apparatus comprising a wafer stage disposed in a processing chamber arranged in a vacuum chamber to hold a wafer as a processing object on a surface of the wafer stage, to conduct processing for the wafer by use of plasma generated in the processing chamber, wherein
the wafer stage comprises grooves, each of the grooves extending from a central portion of a surface on which the wafer is held to an outer circumferential edge of the surface, the grooves including openings at the outer circumferential edge, and
the processing is conducted in a state in which the wafer is held at predetermined height over an upper surface of the wafer stage.

2. The plasma processing apparatus according to claim 1, wherein:
the vacuum chamber is coupled to a vacuum transfer chamber coupled to a second vacuum chamber and an inside of the vacuum transfer chamber is decompressed to vacuum, the wafer being transferred through the inside; and
the wafer is processed in a processing chamber disposed in the second vacuum chamber and is then transferred to the wafer stage and is held thereon.

3. The plasma processing apparatus according to claim 1, wherein:
each of the grooves has a width of 5 mm or less and a depth of 0.7 mm or less.

4. The plasma processing apparatus according to claim 1, wherein:
the wafer stage includes two or more of groove pairs disposed on the surface wherein two grooves of each groove pair are in parallel to each other.

5. The plasma processing apparatus according to claim 1, wherein:
the groove pairs extend in at least three directions from a central portion of the surface of the wafer stage.

6. The plasma processing apparatus according to claim 1, wherein:
a bottom portion of each of the grooves includes a chamfered corner.
